(19) United States
(12) Patent Application Publication
(10) Pub. No.: US 2026/0160813 A1
(43) Pub. Date: Jun. 11, 2026

(54) BATTERY CELL ANALYSIS SYSTEM AND BATTERY CELL ANALYSIS METHOD USING THE SAME

(71) Applicant: KOREA INSTITUTE OF SCIENCE AND TECHNOLOGY, Seoul (KR)

(72) Inventors: Kyung Yoon CHUNG, Seoul (KR); Ji-Young Kim, Seoul (KR); Jiwon Jeong, Seoul (KR); Woo Suk Baek, Seoul (KR)

(21) Appl. No.: 19/213,606

(22) Filed: May 20, 2025

(30) Foreign Application Priority Data
Dec. 10, 2024 (KR) 10-2024-0182536

(51) Int. Cl. G01R 31/36; G01R 31/385; G01R 31/389; H01M 10/613; H01M 10/615

(52) U.S. Cl. CPC G01R 31/3644; G01R 31/385; G01R 31/389; H01M 10/613; H01M 10/615

(57) ABSTRACT

Provided is a battery cell analysis system. The battery cell analysis system includes a battery cell holder fixedly coupled to the inside of vacuum chamber, a power application device apply a voltage to the battery cell holder, a support device configured to support a battery cell and expose at least a portion of a bottom surface of the battery cell, a temperature control device that is in contact with the support device, a power supply device electrically connected to the temperature control device, and a temperature measurement device that is in contact with a top surface of the battery cell. The support device includes an insulation material, and the support device moves from the preliminary space toward the measurement space so as to be selectively disposed on the battery cell holder.

### CROSS-REFERENCE TO RELATED APPLICATION

This U.S. non-provisional patent application claims priority under 35 U.S.C. § 119 of Korean Patent Application No. 10-2024-0182536, filed on Dec. 10, 2024, the entire contents of which are hereby incorporated by reference.

### BACKGROUND

The present disclosure herein relates to a battery cell analysis system and a battery cell analysis method using the same, and more particularly, to a battery cell analysis system configured to transfer and allow a coin cell and/or a pouch cell to be disposed in a vacuum environment, and a battery cell analysis method using the same.

Batteries convert electrical energy into chemical energy, which is stored and subsequently regenerated as electrical energy. Batteries may be produced in various types. For example, they may be manufactured as coin-type batteries and/or pouch-type batteries. The coin type batteries may be referred to as coin cells. The coin cells may operate in various environments. Accordingly, there may be a need to analyze the coin cells that operate in different environmental conditions. Various methods may be employed to analyze the coin cells. For example, electron microscopes may be used to analyze the coin cells. During the analysis process using the electron microscope, the coin cells may be disposed in a vacuum environment.

### SUMMARY

The present disclosure provides a battery cell analysis system compatible with various devices and capable of analyzing a battery cell in diverse environments, and a battery cell analysis method using the same.

The present disclosure also provides a battery cell analysis system capable of transferring and allowing a battery cell to be disposed in a vacuum environment, and a battery cell analysis method using the same.

The present disclosure also provides a battery cell analysis system capable of controlling a temperature of a battery cell, and a battery cell analysis method using the same.

The objects of the present disclosure are not limited to the aforementioned objects, but other objects not described herein will be clearly understood by those skilled in the art from the following description.

An embodiment of the inventive concept provides a battery cell analysis system including: a vacuum chamber configured to provide a measurement space; a load-lock chamber configured to provide a preliminary space selectively connected to the measurement space; a battery cell holder fixedly coupled to the inside of the vacuum chamber; a power application device connected to the battery cell holder to apply a voltage to the battery cell holder; a support device configured to support a battery cell and expose at least a portion of a bottom surface of the battery cell; a temperature control device that is in contact with the support device; a power supply device electrically connected to the temperature control device; and a temperature measurement device that is in contact with a top surface of the battery cell, wherein the support device includes an insulation material, and the support device moves from the preliminary space toward the measurement space so as to be selectively disposed on the battery cell holder.

In an embodiment of the inventive concept, a battery cell analysis method includes: coupling a battery cell to a support device, wherein to the support device exposes at least a portion of a bottom surface of the battery cell; coupling a temperature control device and a temperature measurement device to the battery cell; loading the support device, to which the battery cell is coupled, into a load-lock chamber; loading the support device within the load-lock chamber into a vacuum chamber connected to the load-lock chamber; and observing the battery cell disposed in the vacuum chamber, wherein the loading of the support device into the vacuum chamber includes: moving the support device within the load-lock chamber to a measurement space of the vacuum chamber; and placing the support device on a battery cell holder disposed in the measurement space, wherein the observing of the battery cell includes: applying a voltage to the battery cell through a power application device coupled to the battery cell holder, and controlling a temperature of the battery cell through the temperature control device.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a battery cell analysis system according to an embodiment of the inventive concept;

FIG. 2 is an enlarged cross-sectional view of area X of FIG. 1;

FIG. 3 is an image of a battery cell holder according to an embodiment of the inventive concept;

FIG. 4 is an image of a support device according to an embodiment of the inventive concept;

FIG. 5 is an image of a surface battery cell according to embodiments of the inventive concept;

FIG. 6 is an image showing a state in which the battery cell is disposed on the support device and the battery cell holder according to embodiments of the inventive concept;

FIG. 7 is an image of a cross-sectional battery cell according to embodiments of the inventive concept;

FIG. 8 is an image of a cross-sectional battery cell according to embodiments of the inventive concept;

FIG. 9 is an image of a power application device according to embodiments of the inventive concept;

FIG. 10 is a flowchart showing a battery cell analysis method according to embodiments of the inventive concept;

FIG. 11 is an image of a battery cell holder according to an embodiment of the inventive concept;

FIG. 12 is an image showing a state in which the support device is coupled onto the battery cell holder according to embodiments of the inventive concept;

FIG. 13 is an image showing a state in which the support device is coupled onto the battery cell holder according to embodiments of the inventive concept;

FIG. 14 is an image showing a state in which the battery cell is disposed on the support device and the battery cell holder according to embodiments of the inventive concept;

FIG. 15 is a cross-sectional view of a battery cell analysis system according to embodiments of the inventive concept;

FIG. 16 is an enlarged view of area X of FIG. 15;

FIG. 17 is an image of a temperature control device and a support device to which the temperature control device is coupled according to embodiments of the inventive concept;

FIG. 18 is a cross-sectional view of the temperature control device and the support device to which the temperature adjustment device is coupled according to embodiments of the inventive concept;

FIG. 19 is a plan view of the support device according to embodiments of the inventive concept;

FIG. 20 is a flowchart showing a battery cell analysis method according to some embodiments of the inventive concept;

FIG. 21 is an image showing a state in which the temperature measurement device and the temperature control device are coupled to the battery cell according to some embodiments of the inventive concept; and

FIGS. 22 and 23 are images of a battery cell analysis system to which a microcurrent measurement device is coupled according to some embodiments of the inventive concept.

### DETAILED DESCRIPTION

Exemplary embodiments of technical ideas of the inventive concept will be described with reference to the accompanying drawings so as to sufficiently understand constitutions and effects of the inventive concept. The technical ideas of the inventive concept may, however, be embodied in different forms and should not be construed as limited to the embodiment set forth herein. Rather, these embodiments are provided so that this disclosure will be thorough and complete, and will fully convey the scope of the inventive concept to those skilled in the art. Further, the inventive concept is only defined by scopes of claims.

Like reference numerals refer to like elements throughout the specification. The embodiments herein will be described with reference to a block diagram, a perspective view, and/or a cross-sectional view as ideal exemplary views of the inventive concept. In the drawing, the thicknesses of regions are exaggerated for effective description of the technical contents. Therefore, regions exemplified in the drawings have general properties, and shapes of the regions exemplified in the drawings are used to illustrate a specific shape of a device region, but not intended to limit the scope of the disclosure. Also, although various terms are used to describe various components in various embodiments of the inventive concept, the component are not limited to these terms. These terms are only used to distinguish one component from another component. The embodiments described and exemplified herein include complementary embodiments thereof.

In the following description, the technical terms are used only for explaining a specific exemplary embodiment while not limiting the inventive concept. In this specification, the terms of a singular form may comprise plural forms unless specifically mentioned. The meaning of ‘comprises’ and/or ‘comprising’ used herein does not exclude the presence or addition of one or more other components besides the mentioned components.

Hereinafter, the present disclosure will be described in detail by describing embodiments of the inventive concept with reference to the accompanying drawings.

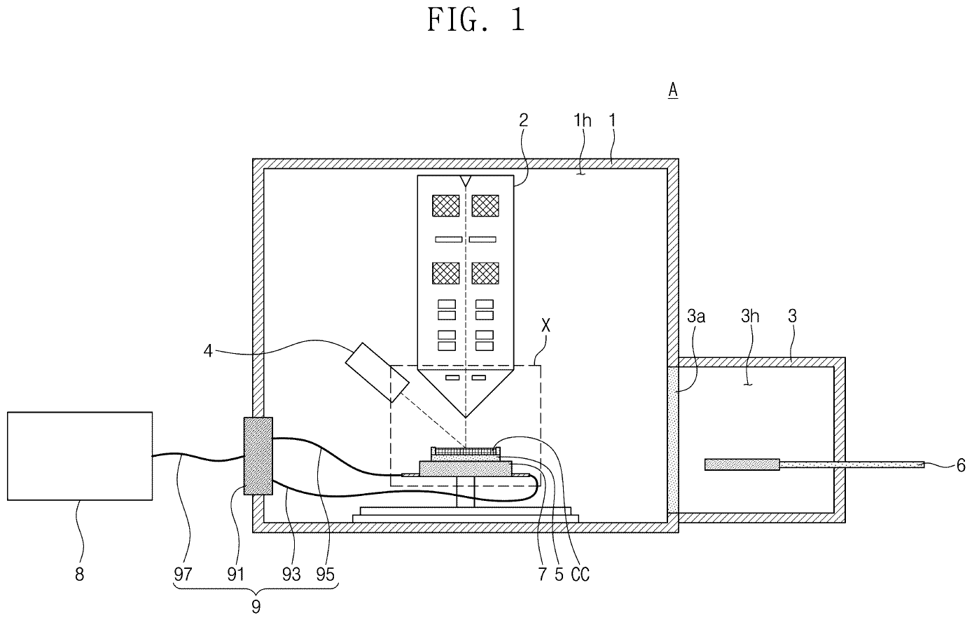

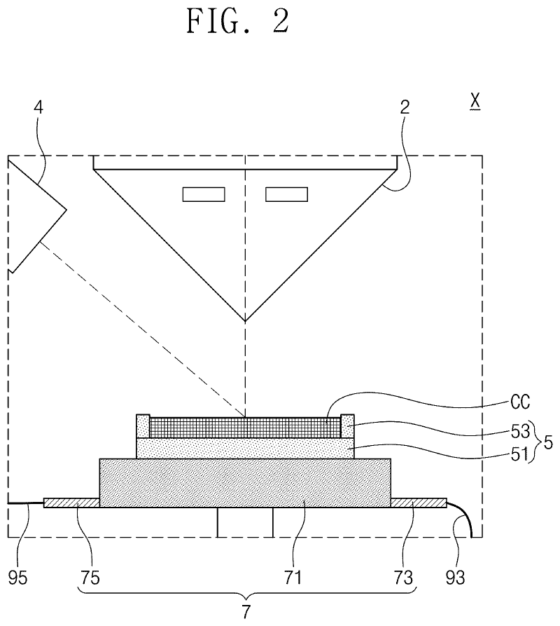

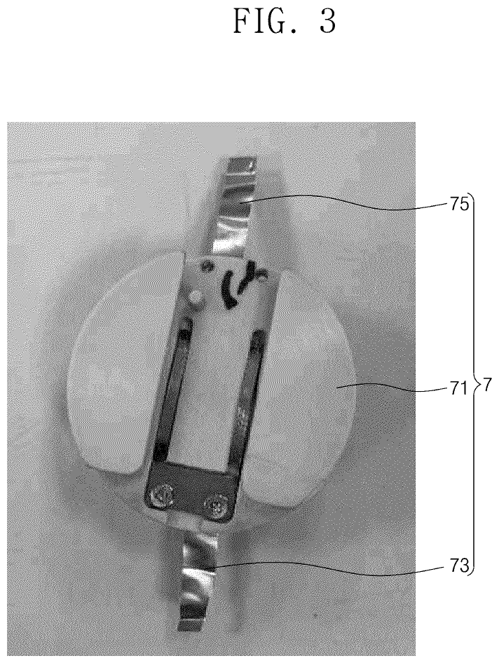

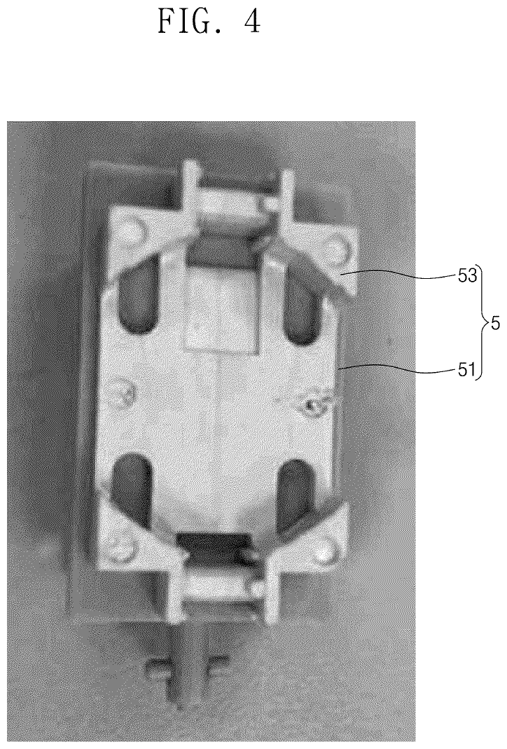

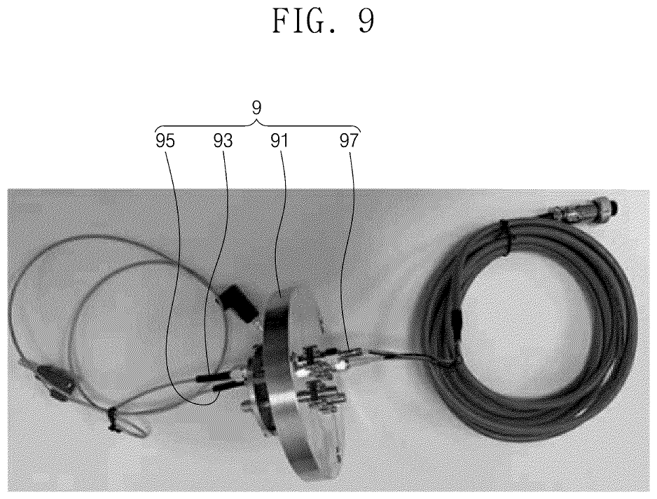

FIG. 1 is a cross-sectional view of a battery cell analysis system according to an embodiment of the inventive concept, FIG. 2 is an enlarged cross-sectional view of area X of FIG. 1, FIG. 3 is an image of a battery cell holder according to an embodiment of the inventive concept, FIG. 4 is an image of a support device according to an embodiment of the inventive concept, and FIG. 9 is an image of a power application device according to embodiments of the inventive concept.

Referring to FIGS. 1 to 4 and FIG. 9, a battery cell analysis system A may be provided. The battery cell analysis system A may perform an analysis on a battery cell CC. The battery cell CC may include a coin cell, but is not limited thereto, and the battery cell CC may also include a pouch cell. However, for convenience, the battery cell CC will be illustrated and described based on a coin cell hereinafter. The coin cell may refer to a coin-shaped battery. The battery cell analysis system A may analyze characteristics of the battery cell CC, for example, during the operation of the battery cell CC. The battery cell CC may be analyzed in its disposed state within the battery cell analysis system A. For this purpose, the battery cell analysis system A may include a vacuum chamber 1, a load-lock chamber 3, a battery cell holder 7, a support device 5, a power application device 9, a vacuum transfer device 6, an analysis device 2, an observation device 4, and a voltage generation device 8.

The vacuum chamber 1 may provide a measurement space 1h. The measurement space 1h may be separated from an external space by the vacuum chamber 1. The measurement space 1h may be connected to a vacuum pump (not shown). The measurement space 1h may be maintained in a substantially vacuum state by the vacuum pump. The battery cell CC may be disposed in the measurement space 1h. The battery cell CC disposed in the measurement space 1h may be analyzed by an analysis device 2. This will be described later in detail.

The load-lock chamber 3 may be coupled to the vacuum chamber 1. The load-lock chamber 3 may provide a preliminary space 3h. The preliminary space 3h may be connected to the measurement space 1h. More specifically, the preliminary space 3h may be selectively connected to the measurement space 1h. For example, the preliminary space 3h may be connected to the measurement space 1h through the opening and closing of a vacuum door 3a. The vacuum pump (not shown) may be connected to the preliminary space 3h. The preliminary space 3h may be brought to a substantially vacuum state by the vacuum pump. This will be described later in detail.

The battery cell CC may be disposed in the measurement space 1h. More specifically, the battery cell holder 7 may be fixedly coupled to the inside the vacuum chamber 1. The battery cell holder 7 may support the support device 5. The battery cell holder 7 may be connected to the power application device 9. The battery cell holder 7 may include a base member 71, a first electrode connection terminal 73, and a second electrode connection terminal 75. The base member 71 may support the support device 5. The first electrode connection terminal 73 may be disposed at one side of the base member 71. The power application device 9 may be connected to the first electrode connection terminal 73. The second electrode connection terminal 75 may be disposed at the other of the base member 71. For example, the second electrode connection terminal 75 may be disposed opposite the first electrode connection terminal 73 with respect to the base member 71. The power application device 9 may be connected to the second electrode connection terminal 75. Each of the first electrode connection terminal 73 and the second electrode connection terminal 75 may include a conductive material. For example, each of the first electrode connection terminal 73 and the second electrode connection terminal 75 may include metal.

The support device 5 may support the battery cell CC. That is, the battery cell CC may be disposed on the support device 5. The support device 5 may be movable. For example, the support device 5 may be movable from the load-lock chamber 3 to the vacuum chamber 1. That is, the support device 5 may move from the preliminary space 3h toward the measurement space 1h. The support device 5 may be selectively disposed on the battery cell holder 7. That is, the support device 5 entering the measurement space 1h may be disposed on the battery cell holder 7. The support device 5 may include a support body 51 and a support pillar 53. The support body 51 may be disposed on the battery cell holder 7. The support body 51 may have a plate shape, but is not limited thereto. The support pillars 53 may be disposed on the support body 51. A plurality of support pillars 53 may be provided. The plurality of support pillars 53 may be spaced apart from each other in a horizontal direction. The battery cell CC may be inserted between the plurality of support pillars 53. However, for convenience, the support pillars 53 will be described in singular form hereinafter.

The power application device 9 may be connected to the battery cell holder 7. The power application device 9 may apply voltage to the battery cell holder 7. For this purpose, the power application device 9 may include a flange 91, a first power transfer member 93, a second power transfer member 95, and a power supply member 97. The flange 91 may be coupled to the vacuum chamber 1. The first power transfer member 93 may connect the first electrode connection terminal 73 to the flange 91. For example, one side of the first power transfer member 93 may be connected to one surface of the flange 91. The other side of the first power transfer member 93 may be connected to the first electrode connection terminal 73. The first power transfer member 93 may include, for example, an alligator clip and a wire, but is not limited thereto. The second power transfer member 95 may connect the second electrode connection terminal 75 to the flange 91. For example, one side of the second power transfer member 95 may be connected to one surface of the flange 91. The other side of the second power transfer member 95 may be connected to the second electrode connection terminal 75. The second power transfer member 95 may include, for example, an alligator clip and a wire, but is not limited thereto. The power supply member 97 may connect the flange 91 to the voltage generation device 8. For example, one end of the power supply member 97 may be connected to the other surface of the flange 91. The other end of a power supply member 97 may be connected to the voltage generation device 8.

The vacuum transfer device 6 may be connected to the load lock chamber 3. The vacuum transfer device 6 may move the support device 5. For example, the vacuum transfer device 6 may move the support device 5 from the preliminary space 3h to the measurement space 1h. For this purpose, the vacuum transfer device 6 may be movable in a horizontal direction. By the vacuum transfer device 6, the support device 5 in the preliminary space 3h may be moved to the measurement space 1h and disposed on a battery cell holder 7. The vacuum transfer device 6 may include, for example, a load lock arm and the like, but is not limited thereto.

The analysis device 2 may observe the battery cell CC. At least a portion of the analysis device 2 may be disposed within the measurement space 1h. The analysis device 2 may irradiate an electron beam and/or a laser beam to the battery cell CC disposed on the battery cell holder 7. For this purpose, the analysis device 2 may include at least one of an atomic force microscope (AFM), a Raman spectrometer, a scanning electron microscope (SEM), and a transmission electron microscope (TEM).

The observation device 4 may detect particles emitted from the battery cell CC. For example, the observation device 4 may detect a secondary electron emitted from the battery cell CC. For this purpose, at least a portion of the observation device 4 may be disposed within the measurement space 1h.

The voltage generation device 8 may be connected to the power application device 9. The voltage generation device 8 may apply power to the battery cell holder 7 through the power application device 9.

The battery cell analysis system A may further include a temperature control device and a temperature measurement device TD. The temperature control device may be, for example, a part of the support device 5. More specifically, the temperature control device may be coupled to the support body. The temperature control device may be coupled to the battery cell exposed through a through-hole 5H. The temperature control device may control the temperature of the battery cell by being coupled thereto. For this purpose, the temperature control device may include a structure that emits and/or absorbs heat. For example, the temperature control device may include a Peltier element and/or a micro heating stage. The temperature control range of the temperature control device may be, for example, from about −55° C. to about 560° C.

The temperature measurement device TD may be coupled to the battery cell. The temperature measurement device TD may be coupled to a top surface of the battery cell disposed on the support device. Through this, the temperature measurement device TD may measure the temperature of the battery cell, which is controlled by the temperature control device.

The temperature control device and the temperature measurement device TD may be electrically connected to the power supply device.

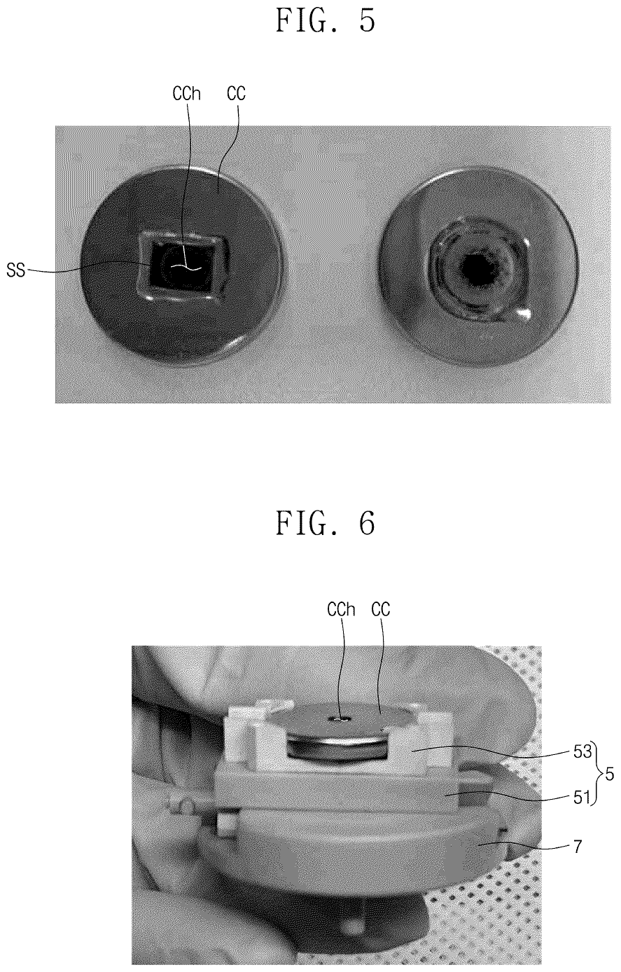

FIG. 5 is an image of the battery cell according to embodiments of the inventive concept.

Referring to FIG. 5, the battery cell CC may provide an observation hole CCh. The observation hole CCh may be recessed downward from the top surface of the battery cell CC. Through the observation hole CCh, the interior of the battery cell CC may be exposed. The observation hole CCh may be sealed with a transparent material. For example, the observation hole CCh may be sealed with SiNx.

FIG. 6 is an image showing a state in which the battery cell is disposed on the support device and the battery cell holder according to embodiments of the inventive concept.

Referring to FIG. 6, the battery cell CC may be disposed on the support device 5. More specifically, the battery cell CC may be disposed between the plurality of support pillars 53. The battery cell CC may be supported by the support body 51. The battery cell CC may be disposed on the support device 5 such that the observation hole CCh is exposed. The support device 5, to which the battery cell CC is coupled, may be disposed on the battery cell holder 7.

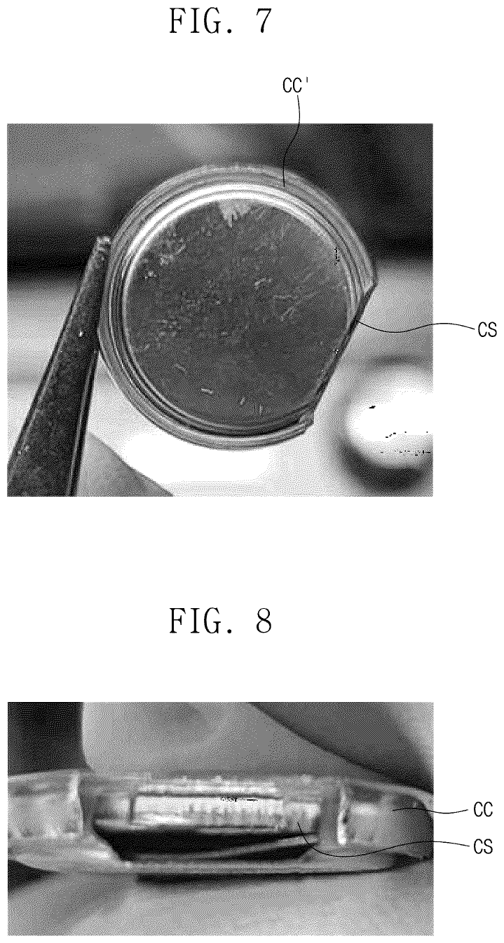

FIG. 7 is an image of the battery cell according to embodiments of the inventive concept, and FIG. 8 is an image of the battery cell according to embodiments of the inventive concept.

Referring to FIGS. 7 and 8, the battery cell CC may be cut along a cross-section parallel to its axis. Through a cut surface CS, the interior of the battery cell CC may be exposed to the outside.

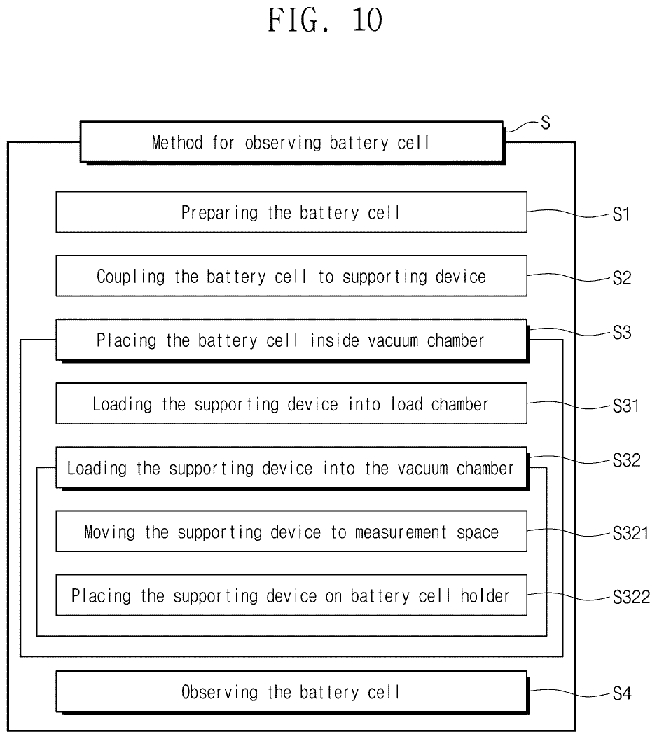

FIG. 10 is a flowchart showing a battery cell analysis method according to embodiments of the inventive concept.

Referring to FIG. 10, a battery cell analysis method S may be provided. The battery cell analysis method S may be a method for analyzing the battery cell CC (see FIG. 1) using a battery cell analysis device A (see FIG. 1) described with reference to FIGS. 1 to 9. The battery cell analysis method S may include preparing the battery cell (S1), coupling the battery cell to the support device (S2), placing the battery cell in a vacuum chamber (S3), and observing the battery cell (S4).

The placing of the battery cell in the vacuum chamber (S3) may include loading the support device into the load lock chamber (S31) and loading the support device into the vacuum chamber (S32).

The loading of the support device into the vacuum chamber (S32) may include moving the support device to the measurement space (S321) and placing the support device on the battery cell holder (S322).

Referring to FIGS. 5 and 10, the preparing of the battery cell (S1) may include exposing the interior of the battery cell CC so that the battery cell CC can be observed by the analysis device. For example, the observation hole CCh may be defined in the battery cell CC. Through the observation hole CCh, the interior of the battery cell CC may be exposed. A solid electrolyte may be disposed inside the battery cell CC. That is, the battery cell CC may include the solid electrolyte. The observation hole CCh may be sealed with a transparent material. For example, the observation hole CCh may be sealed with SiNx or a glass film. Exposing the interior of the battery cell may be performed under vacuum conditions. Accordingly, the observation hole CCh may be defined while the interior of the battery cell is not exposed to the atmosphere.

The above description has been provided with reference to defining the observation hole CCh in the battery cell CC, but is not limited thereto. That is, the preparing of the battery cell (S1) may also include cutting the battery cell as shown in FIGS. 7 and 8. More specifically, the preparing of the battery cell (S1) may include cutting one side of the battery cell CC parallel to its axis to create a cross-section. The cut surface CS of the battery cell CC may be sealed. For example, the cut surface CS of the battery cell CC may be sealed with SiNx.

Referring to FIGS. 6 and 10, the coupling of the battery cell to the support device (S2) may include placing the battery cell CC between the plurality of support pillars 53. The battery cell CC disposed on the support body 51 may have the observation hole CCh facing upward. Coupling the battery cell CC to the support device 5 may be performed under vacuum conditions. The battery cell CC may be coupled to the support device without being exposed to the atmosphere.

Referring to FIGS. 1 and 10, the loading of the support device into the load lock chamber (S31) may include placing the support device 5 to which the battery cell CC is coupled, in the load lock chamber 3. During this process, the vacuum door 3a may be closed, separating the preliminary space 3h from the measurement space 1h. The measurement space 1h may be maintained under vacuum. After the support device 5 is disposed in the preliminary space 3h, the preliminary space 3h may become a vacuum state.

The moving of the support device to the measurement space (S321) may include opening the vacuum door 3a after the preliminary space 3h became a vacuum state. When the vacuum door 3a is opened, the preliminary space 3h and the measurement space 1h may be connected to each other. The support device 5 in the preliminary space 3h may be moved to the measurement space 1h. This process may be performed by the vacuum transfer device 6.

The placing of the support device on the battery cell holder (S322) may include placing the support device 5 inserted into the measurement space 1h on the battery cell holder 7. Accordingly, the battery cell CC may also be disposed on the battery cell holder 7. The battery cell CC may be electrically connected to the power application device 9.

The observing of the battery cell (S4) may include applying a voltage to the battery cell CC through the power application device 9. Subsequently, an electron beam may be irradiated to the battery cell CC. More specifically, an electron beam may be irradiated onto the battery cell CC by the analysis device 2. Accordingly, secondary electrons and the like may be emitted from the battery cell CC. The secondary electrons emitted from the battery cell CC may be detected by the observation device 4.

In another example, a laser beam may be irradiated onto the battery cell CC. More specifically, the laser beam may be irradiated onto the battery cell CC by the analysis device 2. Accordingly, light may be scattered from the battery cell CC. The wavelength of the light emitted from the battery cell CC may be detected by the observation device 4

In another example, a probe may be disposed on the battery cell CC. More specifically, after the probe is disposed in the observation hole CCh, a laser beam may be irradiated onto the probe. The laser beam reflected from the probe may be detected by the observation device 4.

In another example, an ion beam may be irradiated onto the battery cell CC. More specifically, the ion beam may be irradiated onto the battery cell CC by the analysis device 2. Accordingly, a secondary signal may be emitted from the battery cell CC. The secondary signal emitted from the battery cell CC may include, for example, secondary electrons, backscattered electrons, secondary ions, X-rays, and the like. The secondary signal emitted from the battery cell CC may be detected by the observation device 4.

In another example, an electron beam and a laser beam may be sequentially irradiated onto the battery cell CC. Alternatively, an electron beam and an ion beam may be sequentially irradiated onto the battery cell CC. After observing the battery cell using an electron beam, the battery cell may be observed using a laser beam. Alternatively, after observing the battery cell using an electron beam, the battery cell may be observed using an ion beam. Through this process, precise analysis of the same location (or area) of the battery cell may be possible.

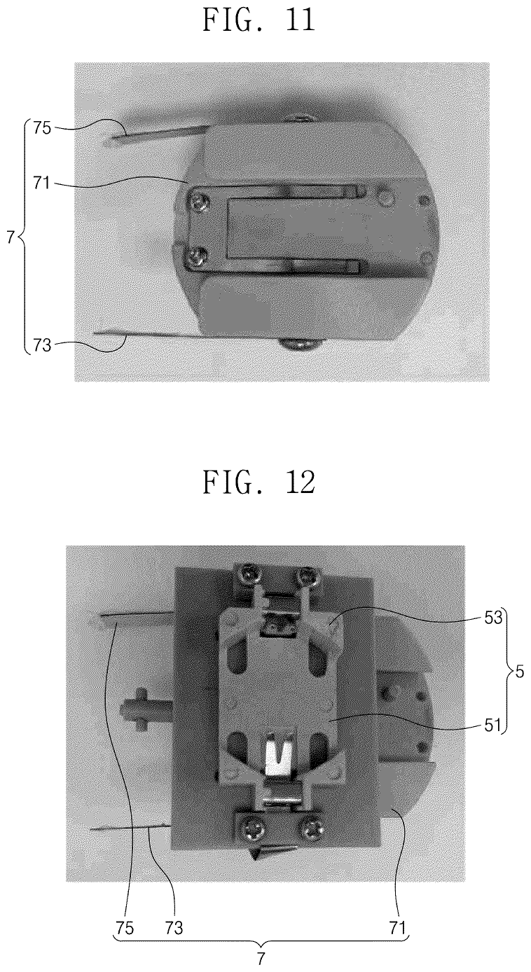

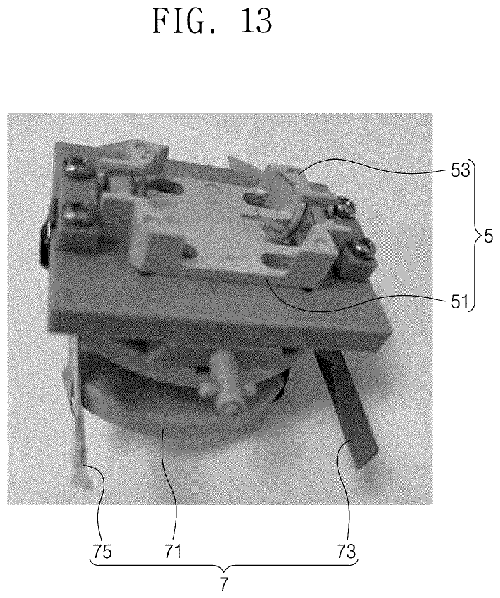

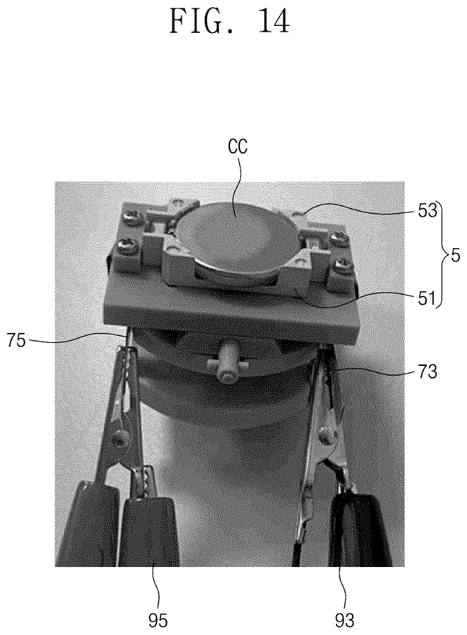

FIG. 11 is an image of a battery cell holder according to embodiments of the inventive concept, FIG. 12 is an image showing a state where a support device is coupled to the battery cell holder according to embodiments of the inventive concept, FIG. 13 is an image showing a state where the support device is coupled to the battery cell holder according to embodiments of the inventive concept, and FIG. 14 is an image showing a state where the battery cell is disposed on the support device and the battery cell holder according to embodiments of the inventive concept.

Hereinafter, for convenience, descriptions of content that is substantially identical or similar to that explained with reference to FIGS. 1 to 10 may be omitted.

Referring to FIG. 11, a battery cell holder 7 may be provided. The battery cell holder 7 may include a base member 71, a first electrode connection terminal 73, and a second electrode connection terminal 75. However, unlike the description provided with reference to FIG. 3, the first electrode connection terminal 73 and the second electrode connection terminal 75 may extend in the same direction from the base member 71. That is, the first electrode connection terminal 73 and the second electrode connection terminal 75 may be parallel to each other.

Referring to FIGS. 12 and 13, the support device 5 may be disposed on the battery cell holder 7. A portion of the support device 5 may be electrically connected to the first electrode connection terminal 73. The other portion of the support device 5 may be electrically connected to the second electrode connection terminal 75.

Referring to FIG. 14, the battery cell CC may be disposed on the support device 5. One side of the battery cell CC may be electrically connected to the first electrode connection terminal 73. A first power transfer member 93 may be coupled to the first electrode connection terminal 73. One side of the battery cell CC may be electrically connected to a voltage generation device 8 through the first electrode connection terminal 73 and the first power transfer member 93. The other side of the battery cell CC may be electrically connected to the second electrode connection terminal 75. A second power transfer member 95 may be coupled to the second electrode connection terminal 75. The other side of the battery cell CC may be electrically connected to the voltage generation device 8 through the second electrode connection terminal 75 and the second power transfer member 95.

According to the battery cell analysis system and the battery cell analysis method using the same, as exemplified by embodiments of the inventive concept, the battery cell may be analyzed under various conditions. For example, the characteristics of the battery cell may be analyzed under operating conditions of the battery cell. Alternatively, the characteristics of the battery cell may be analyzed over a range of temperatures.

According to the battery cell analysis system and the battery cell analysis method using the same, as exemplified by embodiments of the inventive concept, the battery cell may be transferred in a vacuum environment and disposed on the battery cell holder. Accordingly, the time during which the battery cell is exposed to the atmosphere may be removed.

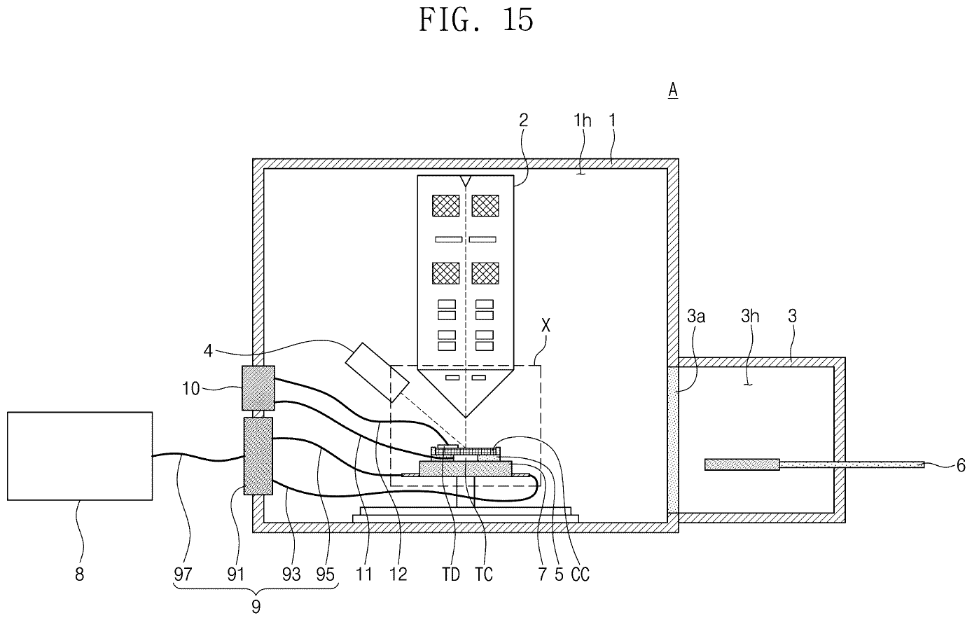

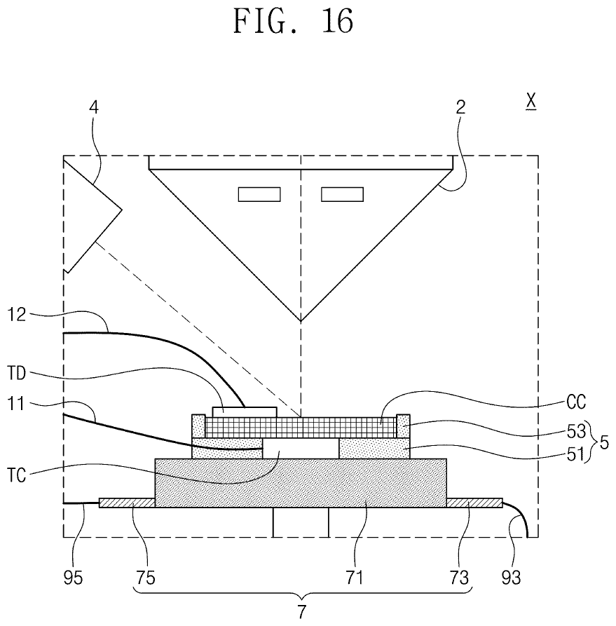

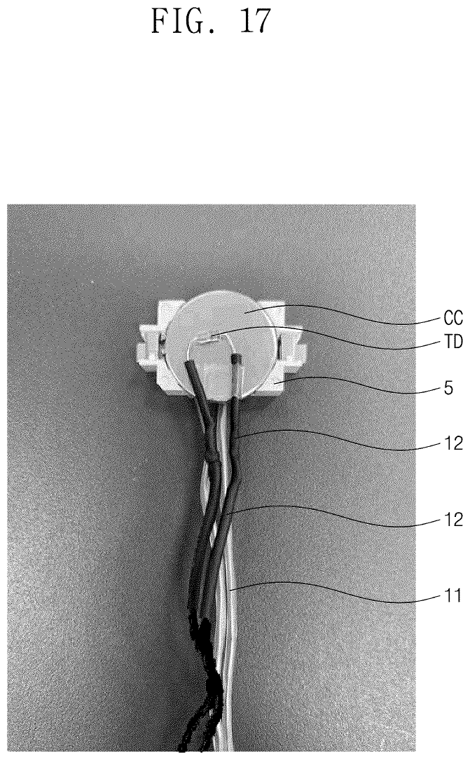

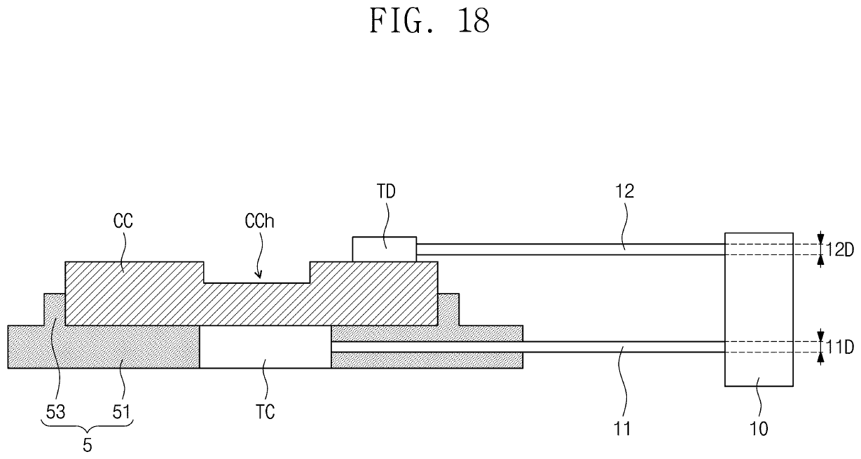

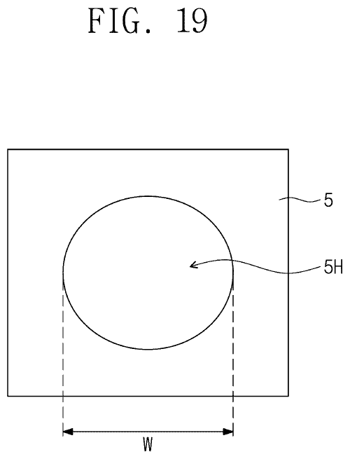

FIG. 15 is a cross-sectional view of a battery cell analysis system according to embodiments of the inventive concept; FIG. 16 is an enlarged view of area X of FIG. 15; FIG. 17 is an image of a temperature control device and a support device to which the temperature control device is coupled according to embodiments of the inventive concept; FIG. 18 is a cross-sectional view of the temperature control device and the support device to which the temperature adjustment device is coupled according to embodiments of the inventive concept; FIG. 19 is a plan view of the support device according to embodiments of the inventive concept; For simplicity of explanation, descriptions of content that is substantially identical or similar to that explained with reference to FIGS. 1 to 10 may be omitted.

Referring to FIGS. 15 and 16, the battery cell analysis system A may further include a temperature control device TC and a temperature measurement device TD. The temperature control device TC may be coupled to the support device 5 to control the temperature of the battery cell CC. The temperature control device TC may have a temperature control range from about −55° C. to about 560° C.

Referring to FIGS. 17 to 19, the support device 5 may expose at least a portion of the bottom surface of the battery cell CC. The support device 5 may include a support body 51 on which the battery cell CC is disposed, and a plurality of support pillars 53 on the support body 51. The support body 51 may include a through-hole 5H passing therethrough. The bottom of the battery cell (CC) may be exposed by the through-hole 5H. The through-hole 5H, for example, may have a diameter W of about 2 mm to about 3 mm.

The temperature control device TC may be coupled to the exposed bottom surface of the battery cell CC. Through this, the temperature control device TC may control the temperature of the battery cell CC. The temperature control device TC may include a structure that emits and/or absorbs heat. The temperature control device TC, for example, may have a temperature increase rate of about 1° C./min to about 12° C./min.

The temperature control device TC may include, for example, a Peltier element and/or a micro heating stage. For example, when absorbing heat, the temperature control device TC may include a Peltier element, and when emitting heat, it may include a micro heating stage.

The temperature measurement device TD may be directly coupled to the top surface of the battery cell CC. The temperature measurement device TD may measure an internal temperature of the battery cell CC. According to some embodiments of the inventive concept, the temperature measurement device TD may be directly coupled to the top surface of the battery cell CC, enabling precise measurement of the internal temperature of the battery cell CC.

The temperature control device TC and the temperature measurement device TD may each be electrically connected to a power supply device 10. The temperature control device TC may be electrically connected to the power supply 10 through a first wire 11. The temperature measurement device TD may be electrically connected to the power supply 10 through a second wire 12. The power supply 10 may have a voltage range of about 1 V to about 24 V and a current range of about 0.5 A to about 1.5 A. The first and second wires 11 and 12 may respectively have thicknesses 11D and 12D of about 0.1 mm to about 0.5 mm. When each of the thicknesses 11D or 12D of the first or second wire 11 or 12 is less than about 0.1 mm, a current of about 0.5 A or more may not be stably supplied.

According to some embodiments of the inventive concept, the battery cell CC analysis system may include the temperature control device TC and the temperature measurement device TD. Through this, the electrical state changes of the battery cell CC according to temperature may be measured in real-time.

Other configurations may be the same as the battery cell CC analysis system described with reference to FIGS. 1 to 9.

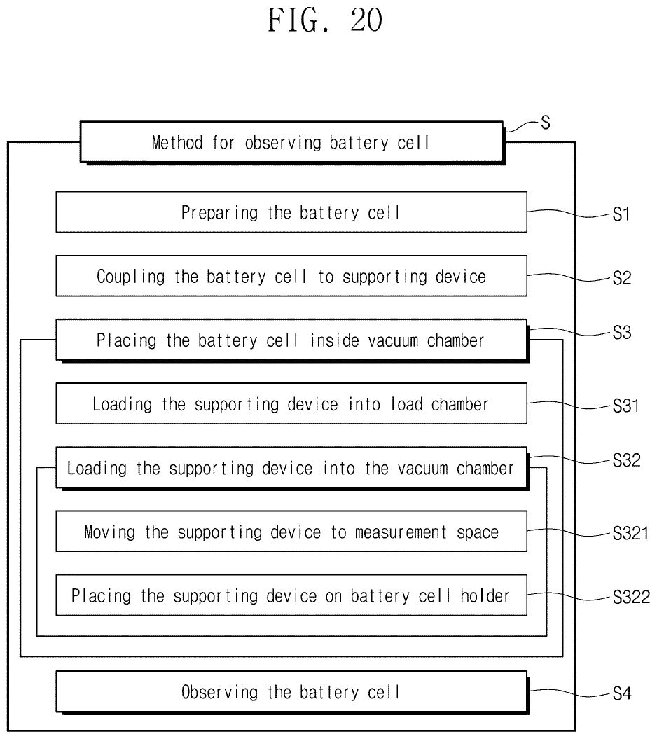

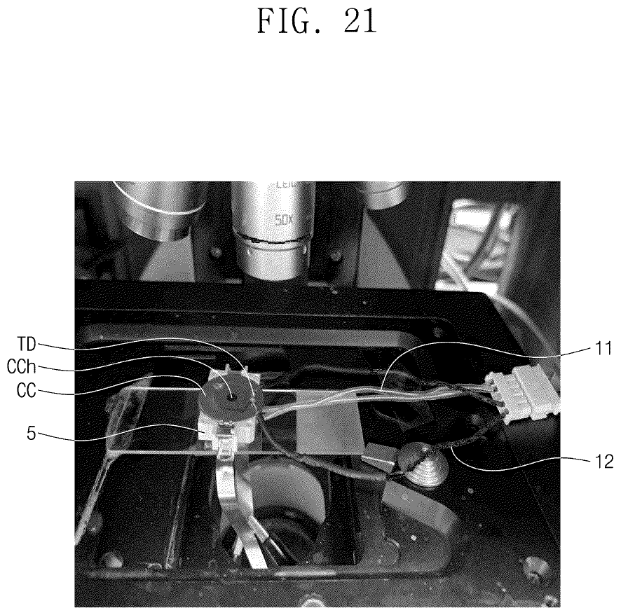

FIG. 20 is a flowchart showing a battery cell analysis method according to some embodiments of the inventive concept. FIG. 21 is an image showing a state in which the temperature measurement device and the temperature control device are coupled to the battery cell according to some embodiments of the inventive concept. For simplicity of explanation, descriptions of content that is substantially identical or similar to that explained with reference to FIGS. 1 to 10 may be omitted.

Referring to FIG. 20, a battery cell analysis method S may include preparing the battery cell (S1), coupling the battery cell to the support device (S2), placing the battery cell in a vacuum chamber (S3), and observing the battery cell (S4).

The placing of the battery cell in the vacuum chamber (S3) may include loading the support device into the load lock chamber (S31) and loading the support device into the vacuum chamber (S32).

The loading of the support device into the vacuum chamber (S32) may include moving the support device to the measurement space (S321) and placing the support device on the battery cell holder (S322).

Referring to FIG. 6, the coupling of the battery cell to the support device (S2) may include placing the battery cell CC between a plurality of support pillars 53. The battery cell CC disposed on the support body 51 may have an observation hole CCh facing upward.

Referring to FIG. 21, the temperature control device TC and the temperature measurement device TD may be coupled to the battery cell CC, which is coupled to the support device. The temperature control device TC may be coupled to the bottom surface of the battery cell CC, and the temperature measurement device TD may be coupled to the top surface of the battery cell CC.

The temperature measurement device TD may not overlap with the observation hole. The temperature measurement device TD may be coupled to an outer portion of the observation hole. Through this, the temperature measurement device TD may not interfere during the observation of the battery cell, which will be described later.

Referring again to FIG. 15, the loading of the support device into the load lock chamber (S31) may include placing the support device 5 to which the battery cell CC is coupled, into the load lock chamber 3. During this process, the vacuum door 3a may be closed, separating the preliminary space 3h from the measurement space 1h. The measurement space 1h may be maintained under vacuum. After the support device 5 is disposed in the preliminary space 3h, the preliminary space 3h may become a vacuum state.

The moving of the support device to the measurement space (S321) may include opening the vacuum door 3a after the preliminary space 3h became a vacuum state. When the vacuum door 3a is opened, the preliminary space 3h and the measurement space 1h may be connected to each other. The support device 5 in the preliminary space 3h may be moved to the measurement space 1h. This process may be performed by the vacuum transfer device 6.

The placing of the support device on the battery cell holder (S322) may include placing the support device 5 inserted into the measurement space 1h on the battery cell holder 7. Accordingly, the battery cell CC may also be disposed on the battery cell holder 7. The battery cell CC may be electrically connected to the power application device 9.

The observing of the battery cell (S4) may include controlling the temperature of the battery cell using the temperature control device TC. It may also include applying a voltage to the battery cell CC through the power application device 9. The controlling of the temperature of the battery cell and the applying of the voltage to the battery cell may be performed simultaneously. However, the inventive concept is not limited thereto, and the controlling of the temperature of the battery cell and the applying of the voltage to the battery cell may be performed separately.

Subsequently, an electron beam may be irradiated to the battery cell CC. More specifically, an electron beam may be irradiated onto the battery cell CC by the analysis device 2. Accordingly, secondary electrons and the like may be emitted from the battery cell CC. The secondary electrons emitted from the battery cell CC may be detected by the observation device 4.

In another example, a laser beam may be irradiated onto the battery cell CC. More specifically, the laser beam may be irradiated onto the battery cell CC by the analysis device 2. Accordingly, light may be scattered from the battery cell CC. The wavelength of the light emitted from the battery cell CC may be detected by the observation device 4

In another example, a probe may be disposed on the battery cell CC. More specifically, after the probe is disposed in the observation hole CCh, a laser beam may be irradiated onto the probe. The laser beam reflected from the probe may be detected by the observation device 4.

In another example, an ion beam may be irradiated onto the battery cell CC. More specifically, the ion beam may be irradiated onto the battery cell CC by the analysis device 2. Accordingly, a secondary signal may be emitted from the battery cell CC. The secondary signal emitted from the battery cell CC may include, for example, secondary electrons, backscattered electrons, secondary ions, X-rays, and the like. The secondary signal emitted from the battery cell CC may be detected by the observation device 4.

In another example, an electron beam and a laser beam may be sequentially irradiated onto the battery cell CC. Alternatively, an electron beam and an ion beam may be sequentially irradiated onto the battery cell CC. After observing the battery cell using an electron beam, the battery cell may be observed using a laser beam. Alternatively, after observing the battery cell using an electron beam, the battery cell may be observed using an ion beam. Through this process, precise analysis of the same location (or area) of the battery cell may be possible. According to some embodiments of the inventive concept, the battery cell CC analysis system may include the temperature control device TC and the temperature measurement device TD. Through this, electrical state changes of the battery cell corresponding to its temperature may be measured.

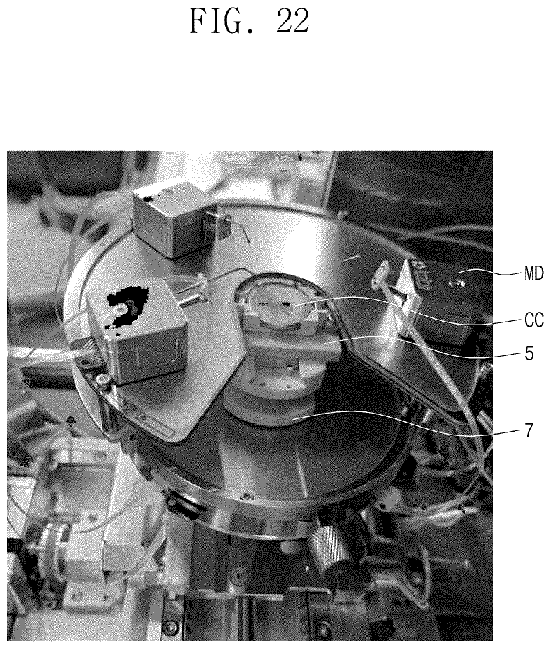

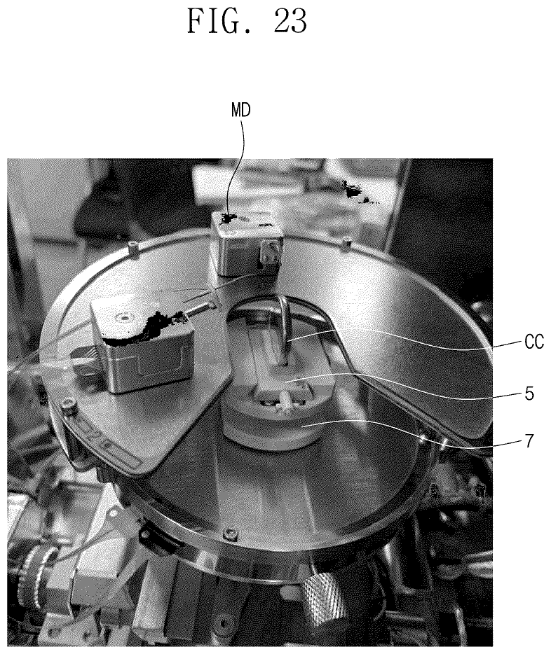

FIGS. 22 and 23 are images of a battery cell analysis system to which a microcurrent measurement device is coupled according to some embodiments of the inventive concept. For simplicity of explanation, descriptions of content that is substantially identical or similar to that explained with reference to FIGS. 1 to 10 may be omitted.

Referring to FIGS. 22 and 23, the battery cell analysis system according to some embodiments of the inventive concept may further include a microcurrent measurement device MD. A plurality of microcurrent measurement devices MD may be provided. The microcurrent measurement device MD may apply an microcurrent to the battery cell CC and measure resistance values within the battery cell CC corresponding to the microcurrent. Through this, regions of the battery cell CC with high electrical resistance and low electrical resistance may be identified and visualized. The microcurrent measurement device MD may be, for example, a miBot by Imina Technologies.

The microcurrent measurement device MD may be electrically connected to a surface or cross-section of the battery cell CC. By applying a microcurrent to the surface of the battery cell CC, the microcurrent measurement device MD may visualize the electrical conductivity distribution of the battery cell. By applying a microcurrent to the cross-section of the battery cell CC, the microcurrent measurement device MD may visualize the electrical conductivity distribution of the battery cell.

According to some embodiments of the inventive concept, the electrical conductivity distribution of the battery cell may be visualized in real time, on a cell-by-cell basis, through the microcurrent measurement device.

According to the battery cell analysis system and the battery cell analysis method using the same of the inventive concept, the battery cell may be analyzed in various environments with compatibility with diverse equipment.

According to the battery cell analysis system and the battery cell analysis method using the same of the inventive concept, the battery cell may be transferred and disposed in the vacuum environment.

According to the battery cell analysis system and the battery cell analysis method using the same of the inventive concept, the temperature of the battery cell may be controlled.

The effects of the present disclosure are not limited to the aforementioned effects, but other effects not described herein will be clearly understood by those skilled in the art from the following description.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A battery cell analysis system comprising:
a vacuum chamber configured to provide a measurement space;
a load-lock chamber configured to provide a preliminary space selectively connected to the measurement space;
a battery cell holder fixedly coupled to the inside of the vacuum chamber;
a power application device connected to the battery cell holder to apply a voltage to the battery cell holder;
a support device configured to support a battery cell and expose at least a portion of a bottom surface of the battery cell;
a temperature control device that is in contact with the support device;
a power supply device electrically connected to the temperature control device; and
a temperature measurement device that is in contact with a top surface of the battery cell,
wherein the support device comprises an insulation material, and
the support device moves from the preliminary space toward the measurement space so as to be selectively disposed on the battery cell holder.

2. The battery cell analysis system of claim 1, wherein the temperature control device has a temperature control range from about −55° C. to about 560° C.,
the power supply device has a voltage range from about 1 V to about 24 V, and
the power supply device has a current range from about 0.5 A to about 1.5 A.

3. The battery cell analysis system of claim 1, wherein the power supply device is electrically connected to the temperature control device through a wire, and
the wire has a thickness of about 0.1 mm to about 0.5 mm.

4. The battery cell analysis system of claim 1, wherein the battery cell holder comprises:
a base member configured to support the support device;
a first electrode connection terminal disposed at one side of the base member; and
a second electrode connection terminal disposed at the other side of the base member;
wherein each of the first electrode connection terminal and the second electrode connection terminal comprises a conductive material.

5. The battery cell analysis system of claim 1, further comprising an analysis device configured to observe the battery cell disposed on the battery cell holder,
wherein the analysis device comprises at least one or more of a scanning electron microscope (SEM), a transmission electron microscope (TEM), an atomic force microscope (AFM), or a Raman spectrometer.

6. The battery cell analysis system of claim 1, further comprising a microcurrent measurement device electrically connected to the battery cell,
wherein the microcurrent measurement device is configured to apply an microcurrent to the battery cell and measure resistance of the battery cell depending on the applied microcurrent.

7. The battery cell analysis system of claim 1, wherein the support device comprises:
a support body disposed on the battery cell holder; and
a plurality of support pillars disposed on the support body,
wherein the support body comprises a through-hole passing therethrough, and
the plurality of support pillars are spaced apart from each other in a horizontal direction so that the battery cell disposed on the support body is inserted between the plurality of support pillars.

8. The battery cell analysis system of claim 7, wherein the through-hole has a diameter of about 2 mm to about 3 mm.

9. The battery cell analysis system of claim 1, wherein the battery cell comprises a solid electrolyte.

10. The battery cell analysis system of claim 1, wherein the temperature control device comprises a Peltier element or a micro heating stage.

11. A battery cell analysis method comprising:
coupling a battery cell to a support device, wherein to the support device exposes at least a portion of a bottom surface of the battery cell;
coupling a temperature control device and a temperature measurement device to the battery cell;
loading the support device, to which the battery cell is coupled, into a load-lock chamber;
loading the support device within the load-lock chamber into a vacuum chamber connected to the load-lock chamber; and
observing the battery cell disposed in the vacuum chamber,
wherein the loading of the support device into the vacuum chamber comprises:
moving the support device within the load-lock chamber to a measurement space of the vacuum chamber; and
placing the support device on a battery cell holder disposed in the measurement space,
wherein the observing of the battery cell comprises:
applying a voltage to the battery cell through a power application device coupled to the battery cell holder, and
controlling a temperature of the battery cell through the temperature control device.

12. The battery cell analysis method of claim 11, wherein the observing of the battery cell comprises:
observing the battery cell through a scanning electron microscope (SEM); and
observing the battery cell through at least one of a transmission electron microscope (TEM), an atomic force microscope (AFM), or a Raman spectrometer.

13. The battery cell analysis method of claim 11, wherein the support device comprises:
a support body disposed on the battery cell holder; and
a plurality of support pillars disposed on the support body,
wherein the support body comprises a through-hole passing therethrough, and
the plurality of support pillars are spaced apart from each other in a horizontal direction so that the battery cell disposed on the support body is inserted between the plurality of support pillars.

14. The battery cell analysis method of claim 13, wherein the through-hole has a diameter of about 2 mm to about 3 mm.

15. The battery cell analysis method of claim 11, wherein the temperature control device has a temperature control range of about −55° C. to about 560° C.

16. The battery cell analysis method of claim 11, wherein the temperature control device comprises a Peltier element or a micro heating stage.
